(19) United States
(12) Patent Application Publication
(10) Pub. No.: US 2025/0029807 A1
(43) Pub. Date: Jan. 23, 2025

(54) APPARATUS AND METHOD FOR ANALYSING A SAMPLE BY MEANS OF ELECTRICALLY CHARGED PARTICLES

(71) Applicant: INTEGRATED DYNAMICS ENGINEERING GMBH, Raunheim (DE)

(72) Inventors: Steve Jackson DJEMPE, Rüsselsheim (DE); Johannes HARTGERS, Mainz (DE)

(21) Appl. No.: 18/714,671

(22) PCT Filed: Nov. 22, 2022
(86) PCT No.: PCT/EP2022/082858

§ 371 Date: May 30, 2024

(30) Foreign Application Priority Data
Dec. 3, 2021 (DE) 10 2021 131 970.6

(51) Int. Cl. H01J 37/09; H01J 37/28

(52) U.S. Cl. CPC H01J 37/09; H01J 37/28; H01J 2237/0264

(57) ABSTRACT

The present invention relates to an apparatus and a method for imaging and/or analyzing and/or processing a sample by means of electrically charged particles, for example using a transmission or scanning electron microscope. The object of the invention is to reduce the influence of magnetic fields.

For this purpose, an apparatus is proposed for imaging and/or analyzing a sample with high resolution by means of electrically charged particles, in particular using an electron beam, the apparatus comprising: a device for providing electrically charged particles; a chamber comprising means for receiving and holding the sample; a device for guiding the electrically charged particles along a central axis M_{Z} towards the chamber; and a detector. A sample arranged in the chamber can be subjected to the electrically charged particles during operation.

Furthermore, a device is provided for compensating for a magnetic interference field and for establishing a preferably elongated compensation volume having its greatest extent along the central axis M_{Z}, wherein an existing magnetic interference field can be reduced within the compensation volume during operation.

### TECHNICAL FIELD

The present disclosure relates to an apparatus and to a method for imaging and/or analyzing and/or processing a sample using electrically charged particles, for example using a transmission or scanning electron microscope. The aim is to reduce the influence of magnetic fields.

### BACKGROUND

Magnetic field compensation based on the feedback control principle has been known. It involves to exploit destructive interference to render virtually or essentially field-free a small volume of space which is also referred to as a compensation volume here. For this purpose, a feedback sensor captures the magnetic interference field, for example the earth's magnetic field, in the vicinity of the object to be protected, and transmits this signal to a control unit. Based on the sensor signals, the control unit calculates a compensation current which is fed to the compensation coils. The latter will then generate a magnetic field which, ideally, destructively overlaps the interference field such that the amplitude of interference is minimized or at least significantly reduced.

In particular appliances that work with accelerated electrons, such as scanning and/or transmission electron microscopes, suffer from electromagnetic interference because it can have a direct negative impact on the trajectory of the electrons required for imaging and therefore on the quality of the results.

Typical installations for such appliances include a large-volume compensation structure in the form of a coil arrangement which often defines a cube-shaped or cuboid-shaped zone in which the compensation field is as homogeneous as possible. The appliance is then placed within this compensation field. Such compensation structures are very bulky on the one hand, but on the other hand they are also very inflexible. They often have to be adapted to the spatial conditions on site and require cumbersome and complex assembly such that the appliances can then be arranged within the structure. The size of the available space or room also limits the size of the appliance.

A more compact arrangement is described in Applicant's document EP 2 544 214 B1. According to certain embodiments it is suggested to arrange two coils around a space in order to compensate for an existing magnetic field within this space. The described system for magnetic field compensation is arranged in such a way that a compensation volume can be formed mainly in the sensitive point of the measuring system. The compensation volume therefore only relates to a very small spatial volume.

Other embodiments suggest to only provide a single coil per spatial direction or per axis instead of a pair of coils per spatial direction. The compensation field will be significantly more inhomogeneous in this case, but will be sufficient for certain applications and saves three coil structures.

What these arrangements for magnetic field compensation have in common is that a specific magnetic field compensation can only be provided within a very limited spatial volume. Magnetic field compensation is therefore only possible, if at all, in a very narrowly defined, essentially point-like spatial volume with dimensions of just a few millimeters.

The achievable magnetic field compensation will therefore already decrease significantly directly within the vicinity or environment of the sample or at least outside this very small spatial volume, such that electromagnetic interference increases rapidly and the trajectory of the electrons is altered on the way to the sample, which will ultimately affect the quality of the measurement results.

This small extension of the spatial volume providing sufficient magnetic field compensation is also unfavorable in the context of larger appliances, since scanning and/or transmission electron microscopes increasingly have longer or higher structures in order to achieve higher accuracy.

This increases the need for a flexible magnetic field compensation that can be easily integrated into the appliance or the environment, but which at the same time also provides a larger spatial volume with sufficient magnetic field compensation.

The inventors have therefore taken on the task of at least mitigating these drawbacks of the prior art.

### GENERAL DESCRIPTION OF THE PRESENT DISCLOSURE

The present disclosure is therefore provided an apparatus and a method for imaging and/or analyzing a sample, which provide for the best possible magnetic field compensation over a larger area or spatial volume.

The aim is to achieve the best possible magnetic field compensation over a greatest possible distance, at least along one predefined spatial direction, without requiring a large-volume compensation structure.

The apparatus and the method for magnetic field compensation should be able to be used in particular on or in conjunction with scanning and/or transmission electron microscopes (SEM or TEM).

It should also be possible to integrate the present disclosure into existing control concepts or to enhance the prior art control concepts.

Particular consideration should be given to the special conditions for operability of the appliances and to the appliance-specific properties.

The device and the method for magnetic field compensation should allow to be implemented or integrated in the best way possible and with little effort into the respective apparatuses for imaging and/or analyzing a sample, in particular in or on scanning and/or transmission electron microscopes, and preferably also in or on those microscopes which include rather high structures of for example more than 1 m, more than 2 m or even more than 3 m.

The present disclosure is provided by an apparatus and a method for imaging and/or analyzing and/or processing a sample with high resolution by means of electrically charged particles according to any one of the independent claims.

Preferred embodiments and further refinements of the present disclosure will be apparent from the respective dependent claims.

According to a first aspect, the present disclosure therefore relates to an apparatus for imaging and/or analyzing and/or processing a sample with high resolution by means of electrically charged particles, in particular using an electron beam, the apparatus comprising
a device for providing electrically charged particles;
a chamber comprising means for receiving and holding the sample;
a device for guiding the electrically charged particles along a central axis M_{Z} towards the chamber; and
a detector;
wherein a sample arranged in the chamber can be subjected to the electrically charged particles during operation;
and a device for compensating for a magnetic interference field and for establishing a preferably elongated compensation volume that has a greatest extent along the central axis M_{Z};
wherein the chamber is preferably arranged within the compensation volume, at least partially;
comprising at least two compensation coils, each of which is provided by at least one turn of a conductor, and wherein at least two compensation coils are arranged next to one another along the central axis M_{Z} or associated therewith;
and wherein an existing magnetic interference field can be reduced within the compensation volume during operation.

During operation, the apparatus allows to subject a sample arranged in the chamber to the electrically charged particles essentially without interference from a magnetic field initially prevailing there. In this way, the measurement can be carried out largely or completely without an impact by magnetic interference fields, so that a sample can be imaged, analyzed and/or processed irrespective of magnetic fields present at the site of the measurement.

The compensation volume may have an elongated shape with a greatest extent along the direction of the central axis M_{Z} of the device. This arrangement makes it possible to compensate for a magnetic interference field present at the installation site of the apparatus in a three-dimensional spatial volume, whereby the interference field can be compensated for both in the horizontal plane and along the vertical.

The apparatus according to the present disclosure for imaging and/or analyzing a sample may be arranged in an upright position during operation, as is often the case with transmission electron microscopes, for example, but it may also be arranged horizontally.

It is assumed that a horizontal plane is defined by spatial directions X and Y, and the perpendicular or orthogonal thereto is referred to as spatial direction Z. With an upright arrangement of the apparatus, the central axis M_{Z} of the apparatus corresponds to the spatial direction Z, and the directions or coordinates X and Y of the apparatus correspond to spatial directions X and Y. During operation, the electrically charged particles can move along the central axis M_{Z} of the apparatus, which therefore extends parallel to the spatial direction Z in an upright arrangement.

With the greatest dimension of the compensation volume being along the direction of central axis M_{Z} of the apparatus, the electrically charged particles can travel along a longest possible path through the compensation volume during operation of the apparatus. This in particular refers to the path from the device for providing electrically charged particles or the device for guiding the electrically charged particles, also referred to as the emitter below, via the location where the sample is accommodated, also referred to as the sample holder below, to the detector which is configured for detecting the electrically charged particles. For this purpose, it is contemplated to have at least two compensation coils arranged next to one another along the central axis M_{Z} or associated therewith.

In addition to these at least two compensation coils arranged along central axis M_{Z}, at least two further compensation coils are provided in an embodiment of the present disclosure, which can be associated with the X and Y coordinates of the apparatus. The axes M_{X} and M_{Y} associated with these at least two additional compensation coils thus correspond to spatial directions X and Y in an upright arrangement. The compensation coils associated with these axes are therefore aligned perpendicular to the at least two compensation coils associated with the central direction M_{Z}.

In this way, it is possible to compensate for an existing magnetic interference field in all spatial directions X, Y, and Z within the compensation volume. It is possible to have a plurality of compensation coils or just a single compensation coil associated with each of the two spatial directions X and Y.

During operation of the apparatus, the compensation coils allow to generate the preferably elongated compensation volume, whereby an existing magnetic interference field, for example the earth's magnetic field prevailing at the installation site and/or interference from the environment, for example in conjunction with a selected installation site, and/or interference from the apparatus itself, can be at least significantly or ideally essentially completely compensated for. The compensation volume thus describes a spatial volume of a magnetic field generated by the compensation coils, where a magnetic interference field that is present there is reduced, preferably to a predefined maximum magnitude of the magnetic flux density.

For this purpose, the feedback control principle may be used, whereby a spatial volume can be rendered virtually or essentially field-free through destructive interference. To this end, a compensation current can be fed to the compensation coils, which can then generate a magnetic field which, ideally, will destructively overlap with the interference field in such a way that the amplitude of interference is minimized or at least significantly reduced. For this purpose, devices for measuring the magnetic flux density are provided, which will be discussed further below.

The inventors have found that measurement inaccuracies caused by a deflection of the electrically charged particles due to interfering magnetic fields can be significantly reduced overall if magnetic field compensation is achieved not only at the location where electrically charged particles are incident on a sample, i.e., the sample holder, but also at the location of the emitter and/or at the location of the detector.

Thus, a least possible impact on the imaging and analysis by the apparatus can therefore be achieved in particular if the magnetic flux density is as small as possible at least at two, preferably at all three of these locations which will also be referred to as sensitive locations below, and/or if the magnetic flux density is as consistent as possible at these sensitive locations.

In other words, particularly high measurement accuracy of the apparatus for imaging and/or analyzing a sample with high resolution by means of electrically charged particles can be achieved if the compensation coils are selected and arranged such that a magnetic field can be compensated for preferably at these three sensitive locations of the apparatus.

The focusing on these three sensitive locations allows to provide smaller compensation coils than is the case with prior art arrangements which involve very large-volume compensation coils. Thus, sufficiently good compensation can be achieved at least at two, preferably three sensitive locations even with two compensation coils which are arranged next to each other along the central axis M_{Z}, and these two compensation coils can be significantly smaller than a large one which covers the entire apparatus and for which appropriate room may have to be provided to accommodate them.

The magnetic field compensation therefore focuses primarily on at least two, preferably the three sensitive locations. If these locations lie collinear to each other along the central axis M_{Z}, which will typically be the case, a slight deflection of the electrically charged particles can be achieved particularly easily at least at two, preferably three sensitive locations using just two compensation coils which are also arranged along the central axis M_{Z}.

According to preferred embodiments of the present disclosure, the distance between adjacent sensitive locations can amount to at least 0.1 m or 0.2 m, in particular at least 0.5 m, preferably at least 1 m, and most preferably at least 1.5 m or even more. This means that the distance between the emitter and the sample holder and/or the distance between the sample holder and the detector can be 0.5 m or more, 1 m or more, or even 1.5 m or more. This means that the distance between the outer sensitive locations, in particular between the emitter and the detector, can be 1 m or more, preferably 1.5 m or more, particularly preferably 2 m or more.

In a preferred embodiment of the present disclosure, the extent in a plane orthogonal thereto can be at least 0.2 m×0.2 m, preferably at least 0.3 m×0.3 m, particularly preferably at least 0.4 m×0.4 m, at least 0.5 m×0.5 m, or more.

In a preferred embodiment, the compensation volume has an extent or dimension in the direction of the central axis M_{Z}, which corresponds to at least 1.5 times, preferably at least twice or even 2.5 times the dimension of the compensation volume in a direction perpendicular thereto, i.e., along any of the coordinates X or Y.

In this way, an elongated, approximately cuboid compensation volume can be established particularly favorably during operation, which can be considered to be homogeneous in the sense of the present disclosure.

The orientation of the compensation volume in relation to the apparatus can be defined by the arrangement of the compensation coils in relation to the apparatus for imaging and/or analyzing a sample.

In a favorable arrangement it is envisaged that a longest possible path of the supplied electrically charged particles can lie within the compensation volume, so that during operation the largest possible section of the path of the electrically charged particles between the device for providing electrically charged particles and the sample lies within the compensation volume.

As stated above, however, it is a desirable aspect of the present disclosure that the highest possible magnetic field compensation can be made possible during operation of the apparatus in particular at the sensitive locations, so that the magnetic flux density is as low as possible at least at two of these sensitive locations. Essentially, these sensitive locations should therefore be kept free of external magnetic interference.

In the context of the present disclosure, compensation volume is understood to mean a spatial volume which has a lower magnetic flux density compared to the magnetic flux density of the surrounding magnetic interference field. A reduction of at least 50% in relation to the magnetic interference field present at the installation site shall be considered as lower here, i.e., the magnitude of the magnetic flux density should be reduced by at least half.

With the arrangement of at least two compensation coils next to each other, the present disclosure makes it possible to establish an elongated compensation volume in which the magnetic flux density is reduced by at least 90%, preferably at least 95%, and most preferably by at least 98%, in particular at the location of the emitter, the sample holder and/or the detector, compared to the magnetic flux density prevailing without the compensation.

This also allows to compensate for changes in the magnetic fields that occur over time. Considerations are based on the typical magnetic flux density resulting from the earth's magnetic field here, which, however, can also be slightly increased or altered by virtue of the apparatus itself or by other equipment present at the installation site of the apparatus.

In this way, an apparatus for imaging and/or analyzing a sample with high resolution using electrically charged particles can be provided, in which, during operation, the magnetic flux density at the location of the emitter and/or of the sample holder and/or of the detector is 0.2 μT or less, preferably 0.1 μT or less, and most preferably 0.05 μT or less, 0.02 μT or less, or even 0.01 μT or less.

In a particularly favorable embodiment of the present disclosure, the difference in the magnitude of the magnetic flux density at least at two, preferably at three sensitive locations is 0.05 μT or less, preferably 0.01 μT or less. This means that during operation the magnetic flux density can be kept almost identical at least at two, preferably at three sensitive locations, which has a particularly favorable effect on the accuracy of the measurements.

In a preferred embodiment, the device for providing the electrically charged particles is provided in the form of an electron microscope, e.g., a scanning electron microscope and/or a transmission electron microscope.

In a further embodiment, the device for providing the electrically charged particles is provided in the form of a lithography device.

In yet another embodiment, the apparatus is provided in the form of an appliance for magnetic resonance imaging, also known as magnetic resonance tomography.

The chamber preferably comes in the form of a vacuum chamber. It can be delimited by lateral walls, a base and a lid. The chamber may include means for receiving and/or holding a sample, such as a sample holder on which a sample can be positioned so that it can be imaged, examined and/or processed using the particles that can be provided by the device.

Accordingly, in a preferred embodiment, the device according to the present disclosure for compensating for a magnetic interference field comprises at least four compensation coils, and these coils can be integrated into the actual appliance or arrangement or even into the environment of the arrangement in such a way that the operability of the arrangement is not significantly impaired.

In the sense of the present disclosure, not only the chamber itself, in which a sample can be accommodated during operation, but also at least a directly adjacent area located outside the chamber can be considered as the compensation volume or can represent the compensation volume, provided that the magnetic flux density is reduced accordingly.

The present disclosure makes it possible to provide an elongated extension of the compensation volume with sufficient magnetic field compensation with comparatively little technical complexity and a compact design, so that not only the chamber but also an area outside the chamber can be encompassed.

This makes it possible to include, at least in sections and ideally completely, the area through which the electrically charged particles travel on their way from the device for guiding the electrically charged particles to the sample and ideally as far as to the detector.

In an embodiment, the compensation volume can therefore have an elongated extension in the spatial direction which encompasses the trajectory of the electrically charged particles, at least sections thereof, ideally completely. In this way, the influence of a surrounding magnetic interference field along the trajectory of the electrically charged particles can be compensated for in a particularly favorable manner.

Accordingly, it is proposed to not reduce the compensation volume to merely a single sensitive point or area, for example of scanning and/or transmission electron microscopes, so-called SEM and/or TEM appliances, as described in document EP 2 544 214 B1, but in particular to also encompass at least an adjacent area around the sensitive point of SEM/TEM appliances.

This is particularly desirable since it has been found that an electron beam, for example, might be sensitively influenced in terms of image quality not only shortly upstream or downstream final focusing and/or filtering before impinging on the sample if exposed to external electromagnetic interference, but also over further stretches between the device for providing electrically charged particles and the impingement on the sample as well as along the path from the sample to the detector.

The compact design of the device according to the present disclosure for compensating a magnetic interference field not only allows to arrange the compensation coils in a room and then arrange the device for providing electrically charged particles, in particular REM/TEM appliances, in this room.

Rather, the compact design also makes it possible to integrate the inventive device for compensating a magnetic interference field directly into the SEM or TEM appliance.

This may be desirable because, on the one hand, the entire apparatus for imaging and/or analyzing a sample with high resolution becomes significantly more flexible and, for example, moving it from one installation site to another becomes much easier.

Another major desirable result is that the specific solution can be configured and optimized with respect to a microscope design and can be operational irrespectively of the conditions at the installation site. This also eliminates the need for a specific analysis of any existing interference fields for the installation site of the apparatus and corresponding site-specific adaptation.

The apparatus according to the present disclosure can therefore be built irrespective of the intended installation site and can therefore be used flexibly.

On the other hand, a shorter distance between the compensation coils and the sample results in better measurement quality, since the compensation can be adjusted more precisely.

According to the present disclosure, each individual compensation coil may have at least one further coil assigned thereto, preferably on the same axis. In this way, a pair of compensation coils can be defined which corresponds to a Helmholtz-like configuration and which is particularly useful to establish homogeneous magnetic fields. In a preferred embodiment, at least one pair of compensation coils is associated with each coordinate X and Y. The at least two compensation coils associated with the central axis M_{Z} each come in the form of a pair of compensation coils.

In this way, an arrangement with a total of at least four pairs of compensation coils can be provided, which allows particularly well to compensate for a magnetic interference field in all spatial directions X, Y, and Z.

The pair of compensation coils may be connected and/or controlled in such a way that only a single compensation coil of the pair of compensation coils can be electrically powered.

The inventors have found that in an arrangement comprising two compensation coils arranged next to each other, in particular comprising two pairs of compensation coils arranged next to each other in the central direction M_{Z}, the controlling and feed-back control for compensation purposes might be more difficult. This can in particular be the case if, for example, the apparatus itself or the device for providing electrically charged particles or the device for guiding the electrically charged particles produces a further magnetic field during operation, which overlaps a magnetic field present at the installation site, so that a magnetic field of unequal strength prevails in the volume to be compensated, which has to be compensated for accordingly.

Although it is possible to influence and thereby reduce the flux density at different locations within the compensation volume by appropriately controlling the individual compensation coils, this can easily lead to overcompensation, especially in an area between the two compensation coils that are arranged along central direction M_{Z}, as the feedback control can be complex.

Although this can be determined by measuring the prevailing magnetic flux density, and the control can be adjusted accordingly, this change may also lead to further overcompensation in the overlap area, which again has to be compensated for.

One reason for this is that the degree of compensation at any point within the compensation volume can be influenced to varying degrees by a plurality of coils. Based on sensor signals, a compensation current can be calculated by the control unit, which is then fed to the compensation coils. However, the magnetic field generated in this way may then overlap the interference field in such a way that the amplitude of interference is not only minimized or at least significantly reduced, but might be amplified again. Thus, undesirable interference may occur especially during a measurement of elongated duration.

It is therefore proposed that the inner coils of the compensation coils or of the pair of compensation coils which are associated with the central direction M_{Z} are designed differently than the outer coils. It has proven to be desirable if a larger current flows through the outer coils than through the adjacent inner coils.

This makes it easier to maximize the extent of the compensation volume in the central direction M_{Z} and to achieve nearly consistent compensation of the interference field within the compensation volume during operation.

This can be achieved, for example, by designing the inner coils with a smaller number of turns compared to the number of turns of the outer coils. In other words, it may be desirable if the number of turns Nᵢ of the inner coils is smaller than the number of turns Nₒ of the outer coils, i.e., to have at least one turn less, so that the following applies in terms of the numbers: Nₒ>Nᵢ.

The different numbers of turns are adjusted so as to minimize the gradient of the magnetic field starting from the center.

As a result thereof, the inner coils have less influence on the compensation volume than the outer coils, so that the occurrence of overcompensation can be largely avoided. Due to the smaller number of turns of the inner coils, a lower current will flow through the inner coils than through the outer coils. If the conductor loops of the coils have the same cross section, the total cross section through which current can flow will thus be smaller for the inner coils than for the outer coils, and a weaker magnetic field will be generated.

Generally, it will be desirable if the cross section of the conductor loops belonging to the inner coil through which current can flow during operation is smaller than the cross section of the conductor loops belonging to the outer coil through which current can flow, preferably by at least 10% and at most 70%, more preferably by at least 15% and at most 65%, and most preferably at least 20% and at most 60%.

Good results were achieved with a number of turns Nₒ=26 of the outer coils and a number of turns Nᵢ=20 or Nᵢ=13 of the inner coils, for example, i.e., a reduction in the cross section through which current can flow by about 20% or 50%. In the case of excessive reduction, the inner coils might no longer provide sufficient compensation.

In this embodiment, it is initially assumed that the radius or cross section of the conductor loops of the inner and outer coils is identical.

According to a further embodiment it is contemplated, alternatively or additionally, to provide the inner and outer compensation coils with a different radius, preferably such that the inner coils have a smaller radius than the outer coils. This also allows to reduce the compensation by the inner coils, so that the risk of overcompensation can be reduced.

In summary, the compensation is based on a two-stage concept whereby, first, a number of turns and/or a size is defined for each coil, and then, during operation, each coil is individually feedback controlled and the current therethrough is adjusted after a corresponding measurement. Each compensation coil can be controlled independently of the other ones.

The device for compensating a magnetic interference field may comprise at least one device for measuring the magnetic flux density, i.e., for detecting or measuring a magnetic interference field.

At least one device for measuring the magnetic flux density may preferably be arranged in the vicinity of the chamber, preferably inside the chamber. This makes it possible to capture the magnetic flux density directly in the area of interaction between the electrons and the sample, and the corresponding compensation coils can be controlled accordingly.

In a preferred embodiment, the apparatus comprises at least two such devices for measuring the magnetic flux density, which can be arranged spaced apart from one another along the central direction M_{Z}. This may be desirable because the compensation volume can have an elongated extension in central direction M_{Z}.

In one embodiment of the present disclosure, at least one device for measuring the magnetic flux density can be associated with the chamber or arranged inside the chamber, and another device for measuring the magnetic flux density can be arranged outside the chamber, preferably in an area between the device for providing the electrically charged particles and the chamber. In this way, it is possible to measure and compensate for an existing interference field not only inside the chamber, but also in an upstream area through which the electrons pass during operation.

Preferably, the device for measuring the magnetic flux density is arranged near the sensitive locations, for example in the vicinity of the emitter, of the sample holder, and/or of the detector.

Since the device for measuring the magnetic flux density may also produce a magnetic interference field, it is advisable to not place the device directly in the vicinity of the sample and of the path of the electrically charged particles.

In a preferred embodiment, due to the preferably elongated extension of the compensation volume, the at least two devices for measuring the magnetic flux density are spaced apart from one another, preferably along central direction M_{Z}, by at least 0.2 m, preferably by at least 0.5 m, and most preferably by at least 1 m, so that particularly good compensation is enabled even with an elongated extension of the compensation volume.

According to one embodiment it is contemplated that the at least one device for measuring the magnetic flux density is arranged in the vicinity of the compensation coil which has a greater number of turns, and that the at least second device for measuring the magnetic flux density is arranged in the vicinity of the compensation coil having a lower number of turns. This allows for an even more precise control of the associated compensation coils, whereby overcompensation can be further reduced.

The device for measuring the magnetic flux density may comprise at least one sensor, preferably a magnetic field sensor or fluxgate magnetometer or saturation core magnetometer. If the device for measuring the magnetic flux density is intended to be arranged inside the chamber, a vacuum-compatible version is recommended. Preferably, the device for measuring the magnetic flux density is able to measure in all three spatial directions.

Furthermore, at least one power supply is provided for the compensation coils, as well as a device for controlling and/or regulating the current in the compensation coils as a function of the captured or measured magnetic interference field. This allows to individually switch a current for each compensation coil or for each conductor, which current may be in a range between 1 and 3 A, for example, so that the desired compensation field can be generated.

Furthermore, at least one device for controlling the compensation coils is provided, preferably on the basis of the measurement of the magnetic flux density, and each individual compensation coil of the pair of compensation coils or the pair of compensation coils for magnetic field compensation is controllable by this device for controlling.

According to one embodiment of the present disclosure, the at least one compensation coil for central direction M_{Z} is arranged at least section-wise on the outer surface and/or the inner surface of the chamber wall, and preferably a recess is provided for this purpose, which extends in the chamber wall, at least sections thereof, and the recess is preferably in the form of a cavity in the chamber wall. For this purpose, a wall of the chamber may provide or have a receiving area for at least a portion of the compensation coil, at least in sections thereof, in particular for at least a portion of the conductor. In one embodiment of the present disclosure, the section for receiving the conductor or receiving area is provided by an outer surface and/or an inner surface of the chamber wall. The compensation coil, in particular the conductor thereof, is arranged on the outer surface and/or on the inner surface of the chamber wall, at least sections thereof. For example, the at least one turn of the conductor is laid along the wall of the chamber. In an alternative or supplementary embodiment, the receiving area or the section for receiving the compensation coil, in particular the conductor, is provided by a recess which extends in the chamber wall, at least sections thereof. The recess may be provided, for example, as a type of trench or depression in the outer surface and/or the inner surface of the chamber wall. In this variation of the present disclosure, a kind of open recess is provided, and the conductor or the compensation coil may lie in the recess in a partially or completely recessed manner.

Preferably, however, the recess comes in the form of a cavity in the chamber wall. In this variation, a kind of closed recess is provided, for example a kind of tubular passage, into which the conductor or the compensation coil can be inserted, portions thereof or completely. The first compensation coil, in particular the conductor, may be directly connected to the chamber, for example by placing the conductor on the chamber wall and/or inserting it into the chamber wall. The first compensation coil, in particular the conductor, may also be indirectly connected to the chamber, for example through a frame onto which the conductor is wound to provide the turns.

The at least one further compensation coil for central direction M_{Z} may be arranged outside the chamber.

In order to enable the sample to be imaged, analyzed and/or processed as precisely as possible, the arrangement is mounted with vibration isolation. Vibration isolation means that the disturbing movements or vibrations that affect the system are intended to be counteracted. Ideally, the movement or vibration is compensated for. This is preferably done in all six degrees of freedom of movement. This is therefore often referred to as vibration compensation. The scope of the present disclosure therefore also encompasses a vibration isolation system comprising at least one apparatus for imaging and/or analyzing a sample with high resolution using electrically charged particles according to the present disclosure, which is mounted with vibration isolation.

The vibration isolation system can be provided as an active and/or passive system.

A passive vibration isolation system is characterized by “simple” mounting with the lowest possible mechanical stiffness in order to reduce a transfer of external vibrations to the load to be isolated. An air bearing and a polymer spring element for mounting are just two examples of a passive vibration isolation system.

In contrast to passive vibration isolation which is characterized by a kind of damping of the vibration or a kind of “isolated” mounting of the load, active vibration isolation is characterized by the fact that the vibration is actively compensated for. A movement induced by a vibration is compensated for by a corresponding counter-movement. For example, an acceleration of the mass induced by a vibration is countered by an acceleration of the same magnitude but with the opposite signs. The resulting total acceleration of the load will be zero. The load will remain at rest, i.e., in the desired position.

Active vibration isolation systems therefore also have a control system, optionally together with a mounting with the lowest possible mechanical rigidity, the control system comprising a control device as well as sensors and actuators which selectively counteract vibrations penetrating the system from outside. The sensors detect movements of the load to be supported. The control device generates compensation signals that are used to control the actuators and thus generate compensation movements. It is possible to use digital or analog control systems or both together, so-called hybrid control systems.

The present disclosure also encompasses a method for imaging and/or analyzing and/or processing a sample with high resolution by means of electrically charged particles, in particular using an electron beam, which uses an apparatus for imaging and/or analyzing a sample with high resolution using electrically charged particles according to the present disclosure.

The method contemplates that electrically charged particles can be provided by a device for guiding electrically charged particles along a central direction M_{Z} towards the chamber and can be directed onto a sample arranged in the chamber, whereby a sample arranged in the chamber can be subjected to the electrically charged particles during operation.

For the purposes of the present disclosure, a device for compensating a magnetic interference field and for establishing a preferably elongated compensation volume is preferably arranged in such a way that the largest extent is parallel to the central direction M_{Z}.

The chamber is preferably arranged at least partially within the compensation volume.

The device for compensating a magnetic interference field may comprise at least four compensation coils, each of which is defined by at least one turn of a conductor, and at least two compensation coils are arranged next to each other along the central axis M_{Z} or are associated therewith.

During operation, an existing magnetic interference field can be reduced within the compensation volume.

In a preferred embodiment, the compensation volume may therefore encompass both the area including the sample arranged in the chamber and the area through which the supplied electrically charged particles pass, at least sections thereof.

These sections may encompass the focusing and/or filtering of the electrically charged particles before they impinge on the sample, for example, so that an interference field can also be compensated for in these areas.

The method according to the present disclosure can be carried out in particular by using the above-mentioned apparatus according to the present disclosure.

The apparatus according to the present disclosure is in particular configured for performing the method according to the present disclosure.

In this way, it is possible with the apparatus according to the present disclosure, in particular in conjunction with a scanning or transmission electron microscope, to provide a resolution of down to 100 pm, preferably down to 60 pm, and most preferably down to 50 pm, or even down to 40 pm.

The samples may have structural elevations in the central direction M_{Z} in a range from 1 nm to several micrometers, preferably up to at least 3 μm or more.

The apparatus according to the present disclosure and the method according to the present disclosure for magnetic field compensation can be used in particular on or in conjunction with scanning and/or transmission electron microscopes (REM or TEM).

The apparatus can also be integrated into existing control concepts, or the prior art control concepts can be enhanced.

In this way, a particularly high degree of flexibility is provided. This allows for a flexible setup. For this purpose, the apparatus can be provided in modular form or as a module or in individual modules and can be easily assembled on site.

This also makes it possible to provide magnetic field compensation for larger scanning and/or transmission electron microscopes with a large overall height or high superstructures, and which may have a height of 1 m or more, or even 2 m or more, or even 3 m, or even more. At the same time, significantly smaller rooms can be used for this purpose than was previously the case.

Conventional devices for magnetic field compensation, by contrast, require large or even very large rooms to accommodate the devices for magnetic field compensation; for example, a transmission electron microscope with an installation height of 2 m requires a large cage of approximately 8 m to accommodate the coils. This means that special rooms such as suitable halls had to be provided for such microscopes, which significantly reduces the possibilities for installation.

Further details of the present disclosure will be apparent from the description of the illustrated embodiments and the appended claims.

### BRIEF DESCRIPTION OF THE DRAWINGS

FIGS. 1a, 1b show an arrangement of compensation coils according to the prior art;

FIG. 2 shows the gradient of the magnetic field in central direction M_{Z} for the arrangement of FIGS. 1a, 1b;

FIG. 3 shows an inventive arrangement of compensation coils according to an embodiment comprising a total of four pairs of compensation coils;

FIG. 4 shows the gradient of the magnetic field in central direction M_{Z} for the arrangement of FIG. 3;

FIG. 5 shows the profile and strength of the magnetic compensation field for the inventive arrangement of compensation coils according to FIG. 3;

FIGS. 6a, 6b schematically show a scanning electron microscope in a cross-sectional view (FIG. 6a), with the associated beam guidance (FIG. 6b).

### DETAILED DESCRIPTION OF THE PRESENT DISCLOSURE

In the following detailed description of preferred embodiments, the same reference numerals designate substantially similar parts in or on these embodiments, for the sake of clarity. However, to better illustrate the present disclosure, the preferred embodiments shown in the figures are not always drawn to scale.

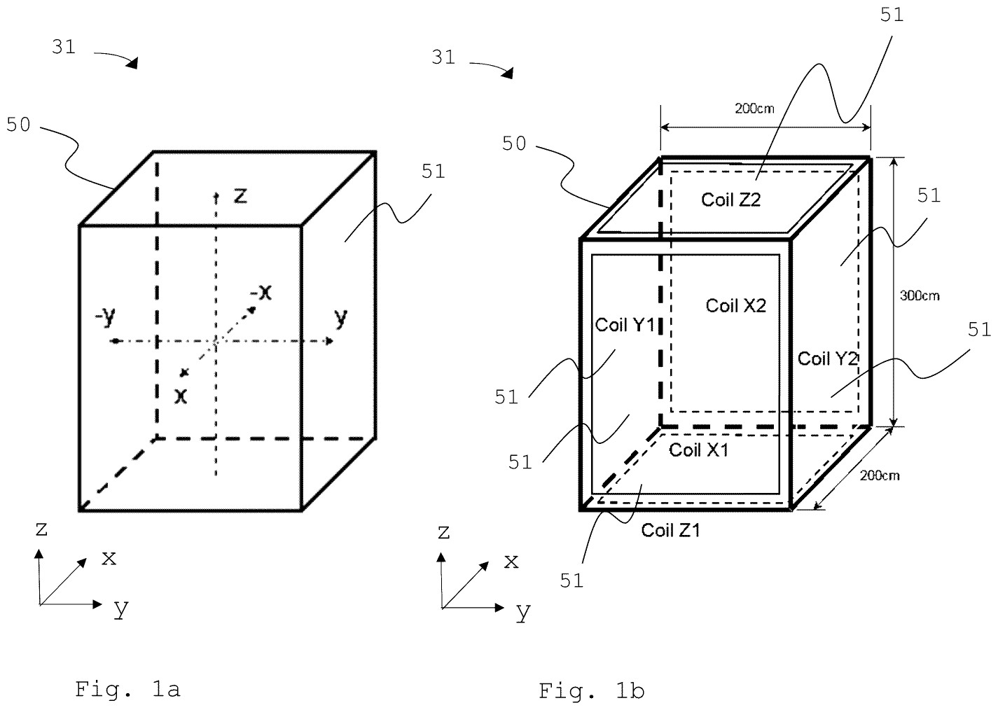

FIGS. 1a, 1b show an arrangement of compensation coils or a device 31 for magnetic field compensation according to the prior art. For the sake of clarity, FIG. 1a shows the spatial directions X, Y and Z using the example of a cuboid cage 50, which makes it easy to arrange coils in a Helmholtz configuration, for example in the area of the respective faces 51.

FIG. 1b shows this cage 50, with exactly one compensation coil (“coil”) associated with each face 51. These compensation coils are not shown in the present FIG. 1a. In the present example, the cage 50 has an extent in the X and Y directions of 200×200 cm and a height of 300 cm.

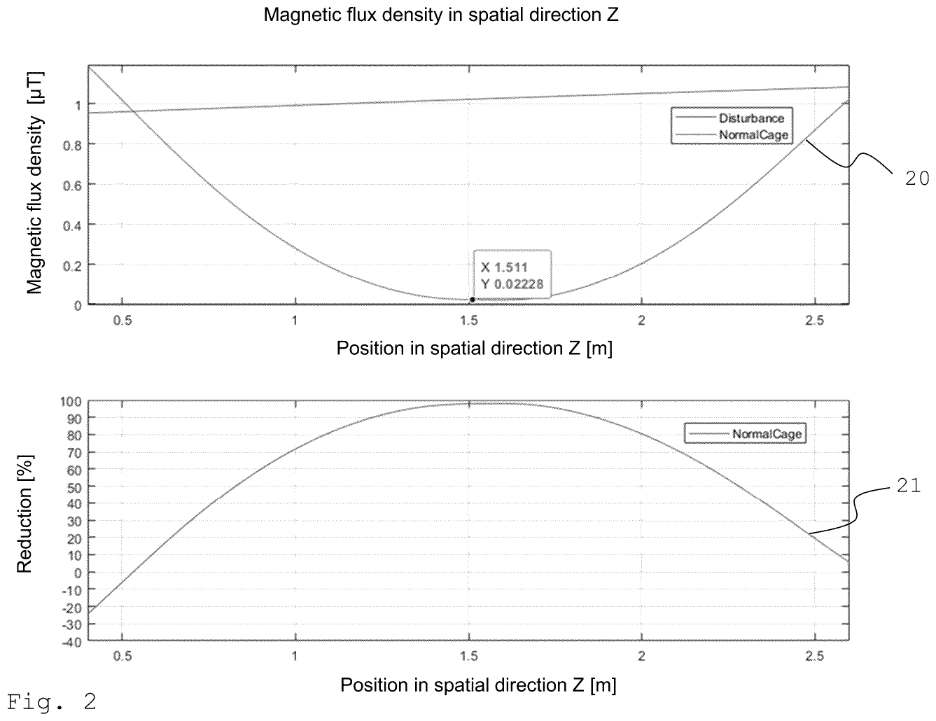

FIG. 2 shows the gradient of magnetic flux density in spatial direction Z using the example of the cage 50 from the embodiment of FIG. 1b. What is shown is the magnitude of magnetic flux density by way of a gradient 20 along the central axis perpendicular to the area spanned by spatial directions X and Y along the height of the cage 50.

The graph shows that by virtue of the compensation coils according to the coil arrangement of FIG. 1b, the magnetic field can be compensated very well in the area near the center or in a central area, whereas the magnetic field has a larger gradient in the outer area or in the vicinity of the compensation coils.

The graphs show that the extent of the compensation volume with a magnetic flux density of, for example, 0.2 μT or less is less than 1 m in spatial direction Z. For appliances having an overall height of 2 m, for example, a compensation of no more than around 1 μT can be provided in spatial direction Z, which might be too high for particularly sensitive devices. Gradient 21 in the lower graph, which indicates the reduction in %, not only shows that a compensation between 0 and up to almost 100% can be achieved over an extent of about 2 m with the arrangement of FIG. 1b, but that overcompensation may also occur, in particular in the peripheral areas, which amplifies the existing interference field.

The zone in which a compensation of almost 100% can be achieved and which will thus be virtually free of interference in terms of a magnetic field has a very small extent in spatial direction Z and amounts to only a few centimeters.

This means that the arrangement of the compensation coils according to the prior art can only provide a very small spatial volume in which actual magnetic field compensation is achieved, or that the compensation coils have to be dimensioned very large in order to achieve better magnetic field compensation.

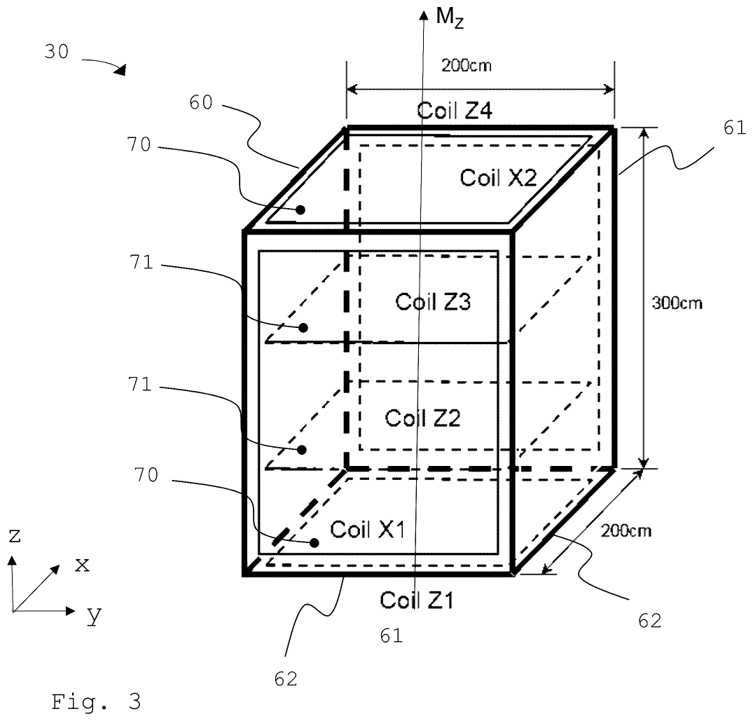

FIG. 3 shows an inventive arrangement of compensation coils according to a particularly preferred device 30 for compensating for a magnetic interference field, which comprises a total of four pairs of compensation coils. Arrangements which provide only one compensation coil on an axis instead of one pair or instead of all pairs of compensation coils, for example, or only two compensation coils along the central axis M_{Z}, are of course also possible and conceivable. However, symmetrical structures, such as the present one allows to establish a comparatively larger, more homogeneous compensation volume.

In the illustrated embodiment, the four pairs of compensation coils are each provided in a Helmholtz-like arrangement in a cage 60, comprising one pair of compensation coils arranged in each of spatial directions X and Y, and two pairs of compensation coils next to each other in spatial direction Z.

If the device 30 for compensating a magnetic interference field is integrated into an apparatus for imaging and/or analyzing a sample, which is set up in an upright position during operation, spatial direction Z corresponds to the central axis M_{Z} of this device, which is indicated in this diagram for the sake of illustration. The apparatus is not illustrated in this view.

The illustrated arrangement of the device 30 for compensating a magnetic interference field defines a cuboid cage 60 which defines a spatial volume having a square base which is defined by the two edges 62 parallel to spatial directions X and Y, and the edge 61 which is associated with spatial direction Z and represents the longest edge in the example. During operation, interference field compensation can be achieved within the spatial volume defined by the cage 60.

In the illustrated embodiment, the base of the cage, i.e., the length of edges 62, is 2 m×2 m, and the height, i.e., the length of edge 61, is 3 m. In favorable configurations, the length of the largest edge, i.e., the height, is at least 1.1 times the length of an edge 62 of the base, so that the cage is rather cuboid in shape than cube-shaped. This is due to the fact that two pairs of coils are associated with the associated central axis M_{Z}. In this way, the preferably elongated compensation volume can be established with an elongated extension along the central axis M_{Z}, which therefore particularly favorably also encompasses the path of the electrically charged particles supplied during operation along this direction, at least sections thereof.

The ratio of the edge length of a base of the cage to the longest edge 61 for a coil configuration comprising two pairs of coils arranged next to each other is in a range between 1.1 times and up to three times, most preferably twice or 1.5 times, as shown in the embodiment of FIG. 3.

It will be appreciated that it is also possible and conceivable to arrange additional compensation coils or pairs of compensation coils next to each other along a spatial direction such as the spatial direction Z. In this way, an even longer compensation volume can be created. However, control might prove to be more complicated in this case, since overcompensation might occur in the overlap area between neighboring coils on the same axis, which in turn would have to be compensated for using suitable control strategies.

In a cage arrangement with three compensation coils or pairs of compensation coils next to each other, a ratio of the edge length of a base of the cage to the longest edge 61 can be between 1.1 times and up to three times or even more, for example 3.5 times or four times, which means that a height of 6 m, 7 m, or 8 m is possible with a base of 2 m×2 m. However, this also means that a sufficiently large room would have to be provided.

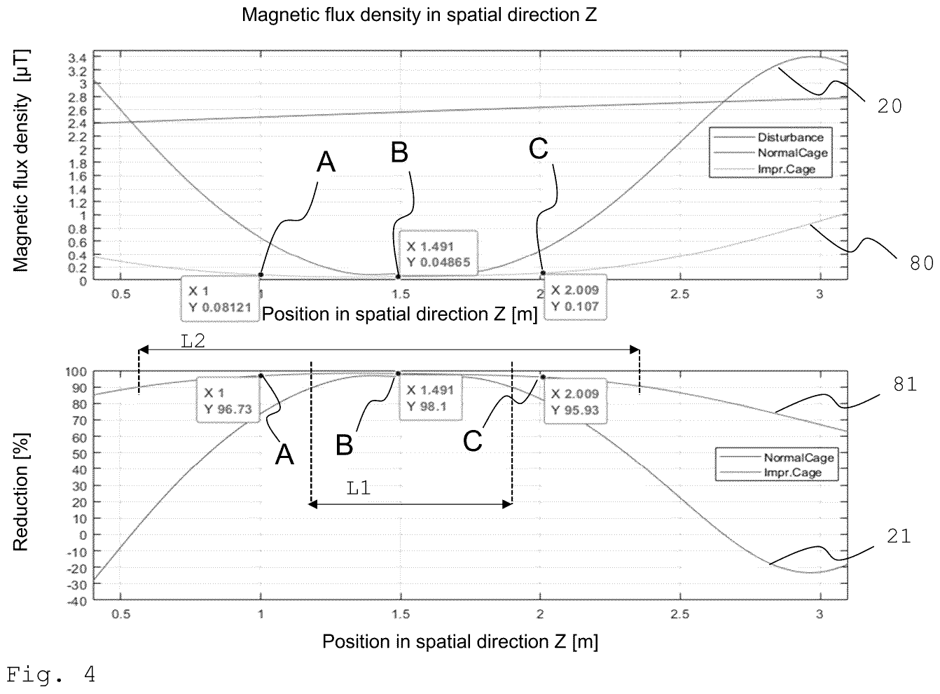

FIG. 4 shows the gradients 80, 81 of the magnetic field in spatial direction Z, i.e., along the central axis M_{Z} of the device for the arrangement of FIG. 3, and the gradients 20, 21 from FIG. 2 representing the prior art arrangement are also shown, for purposes of comparison. Accordingly, the gradients 80, 81 show the reduction in the magnetic flux density that can be achieved with the device 30 according to the present disclosure for compensating a magnetic interference field in terms of the intensity of the reduction and the spatial extent in spatial direction Z. The underlying arrangements of the compensation coils according to FIG. 1 and FIG. 3 are the same in terms of dimensions. In other words, the size of cages 50, 60 is the same.

The upper graph illustrates the magnetic flux density in μT along the central axis M_{Z} of the compensation volume during operation; the lower graph shows the degree of reduction in magnetic flux density in percent, also along the central axis M_{Z}. Gradient 80 shows the magnitude of the magnetic flux density along central axis M_{Z} or in spatial direction Z, and gradient 81 shows the degree of reduction in the magnetic flux density.

In comparison to the gradients 20, 21 of the magnetic field for the arrangement shown in FIG. 1, this graph shows very clearly that a significantly stronger compensation is possible and that this compensation has a significantly larger extent or dimension in spatial direction Z.

The great benefit of the present disclosure is shown by the embodiment included in the lower graph, in which it is assumed that the compensation volume can reduce an existing interference field, i.e., the magnetic flux density, by at least 90%. In this example, gradient 21 gives a length L1 in which the reduction is 90%, which corresponds to the extent of the compensation field along spatial direction Z with this arrangement of the compensation coils. The length L1 is approximately 0.7 m in the example. In comparison, the length indicated by L2 shows the extent of the compensation field along spatial direction Z for the arrangement of the compensation coils according to the present disclosure, which results from the gradient 82. The length L2 is approximately 1.8 m in this example. This means that with the same outer dimensions of cages 50, 60, a significantly longer compensation volume can be provided with the same degree of compensation compared to the prior art arrangement.

For a better illustration, the locations of the sensitive locations of the apparatus are also shown in the diagram of FIG. 4, being labeled A for the emitter, B for the sample holder, and C for the detector. Thus, the diagram also shows the distances between these sensitive locations for the apparatus for imaging and/or analyzing a sample with high resolution using electrically charged particles, on which this example is based, in relation to the compensation volume. In the embodiment, the distance between the emitter and the sample holder is approximately 0.5 m, and the distance between the sample holder and the detector is approximately 0.5 m.

For the purposes of the present disclosure, the distance between the emitter and the sample holder and/or the distance between the sample holder and the detector can be 0.1 m or more, 0.2 m or more, in particular 0.5 m or more, 1 m or more, or even 1.5 m or more. Accordingly, the distance between emitter and detector can also be 1 m or more, preferably 1.5 m or more, most preferably 2 m or more.

As can be seen from FIG. 4, the magnetic flux density at the location of the emitter and/or of the sample holder and/or of the detector is 0.2 μT or less, preferably 0.1 μT or less, and most preferably 0.05 μT or less, 0.02 μT or less, or even 0.01 μT or less. In the embodiment, the magnetic flux density at the location of the emitter and of the detector is approximately 0.15 μT, and at the location of the sample holder it is approximately 0.10 T.

Accordingly, the difference in the magnitude of the magnetic flux density at least at two, preferably at three sensitive locations including the emitter, the sample holder and/or the detector is approximately 0.05 μT in the embodiment, while even smaller differences of approximately 0.01 μT or less can be achieved with other configurations.

This means that significantly larger appliances or apparatuses with larger superstructures can be operated together with the inventive device 30 for compensating a magnetic interference field, with the same possibilities for compensation.

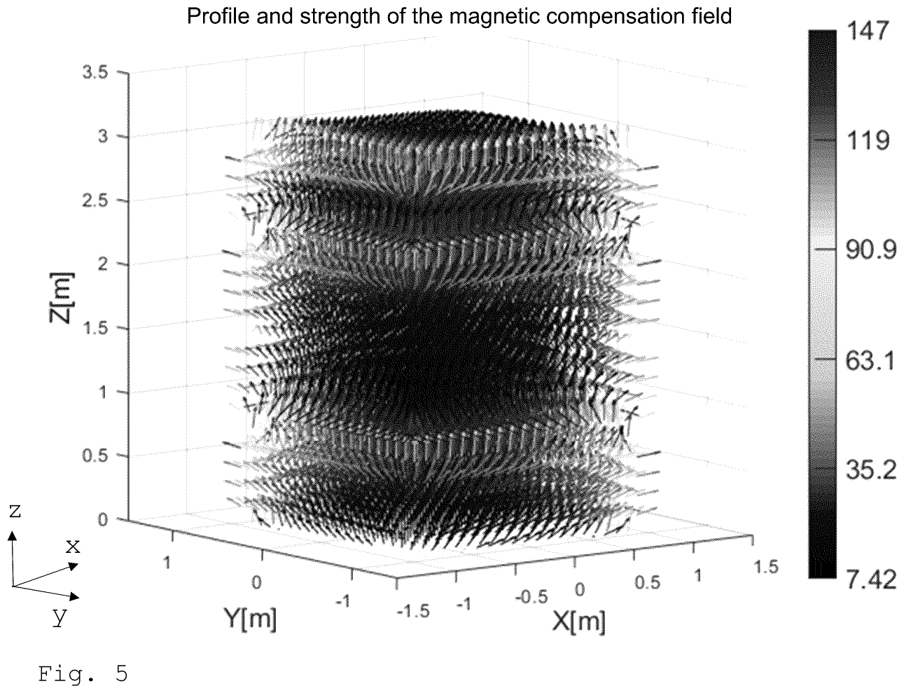

FIG. 5 shows the profile and strength of the magnetic compensation field for the arrangement of compensation coils according to the present disclosure as shown in FIG. 3. The inventive arrangement of the compensation coils makes it possible to provide an approximately cuboid compensation volume with very high homogeneity.

In the embodiment described, the compensation volume has a base area of approximately 0.8 m×0.8 m; the extent in spatial direction Z is approximately 2.8 m.

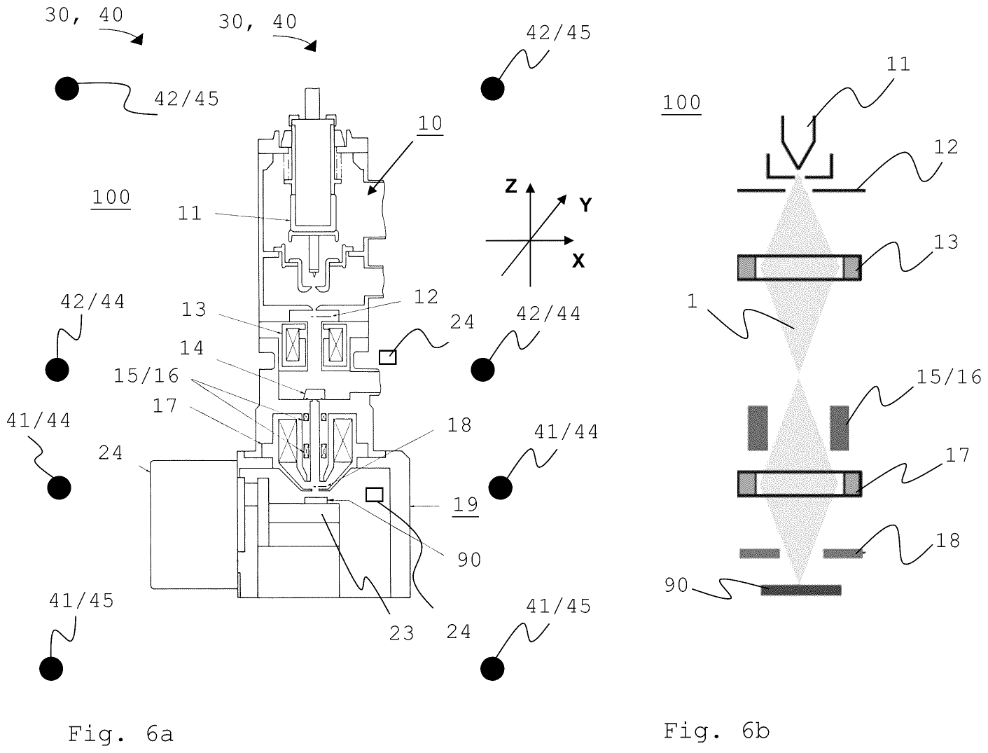

FIGS. 6a and 6b show a schematic cross-sectional view (FIG. 6a) of a scanning electron microscope and the associated beam guidance (FIG. 6b).

The present disclosure shall now be illustrated in more detail using the example of a scanning electron microscope 10. FIG. 6a shows the scanning electron microscope 10 in cross section. FIG. 6b shows an associated beam guidance of the electrons 1. The function will only be outlined briefly: The electrons 1 as electrically charged particles are generated by an electron gun 11. By applying an extraction voltage and an acceleration voltage, the electrons 1 are directed onto the sample 90. A plurality of focusing means and/or deflection means and/or apertures are arranged in the beam path in order to allow to adjust the trajectory and/or the beam shape of the electrons 1 and/or the imaging properties accordingly.

What is provided for this purpose here, by way of example, is a first aperture 12 for beam monitoring, a condenser lens 13, first and second deflection means 15 and 16, in particular for scanning the sample 90, an objective lens 17, and an objective aperture 18 as the last aperture upstream of sample 30, which is preferably arranged so as to be movable for scanning the sample 90. Moreover, a valve 14 is arranged in the beam path. The sample 90 is arranged in a chamber 19 on a sample holder 23. The position of the sample 90 or of the sample holder 23 relative to the electron beam 1 can be changed, for example by a manipulator 24.

The apparatus 100 comprises the electron microscope 10 and the chamber 19. A vacuum is created inside the scanning electron microscope 10 and inside the chamber 19. The electrons 1 impinge on the sample 90 and trigger secondary electrons there. These secondary electrons allow conclusions to be drawn about the properties of the sample 90 under examination. By scanning the sample 90, it can be examined point by point. For example, the backscattered electrons can be captured by a detector (not shown) and can then be examined.

In addition, two compensation coils 41, 42 are indicated in the diagram, which are arranged according to the present disclosure, next to each other in the spatial direction Z. These two coils 41, 42 are each defined by a pair of compensation coils 44, 45, in order to compensate for a magnetic interference field, here in the sheet plane X-Z. Preferably, a pair of compensation coils is also provided for each of the two spatial directions X and Y. A compensation coil 41, 42 is provided by at least one turn of a conductor. The compensation coils 41, 42 form part of a system 40 for magnetic field compensation. The system 40 in turn forms part of the apparatus 100.

Here, the compensation coils 41, 42 cover the entire apparatus 100. Accordingly, the entire spatial volume covered by the compensation coils 41, 42 is rendered virtually field-free by virtue of destructive interference.

The compensation volume generated by the compensation coils 41, 42 is not only provided in the volume between the objective lens 17 or the aperture 18 and an upper surface of the sample 30 on which the electron beam 1 is incident. The compensation volume provided includes both the interaction area of the electron beam 1 with the sample 90 and the trajectory of the electrons 1 along the path from the device for providing electrically charged particles, i.e., the electron gun 11 in the embodiment.

The system 40 for magnetic field compensation according to the present disclosure is further characterized in the embodiment in that the adjacent inner coils 44 of the pairs of compensation coils are designed differently in comparison to the outer coils 45. It has proven to be helpful if a larger current flows through the outer coils 45 than through the adjacent inner coils 44.

Therefore, in the embodiment, the inner coils 44 are equipped with a smaller number of turns compared to the number of turns of the outer coils 45. Accordingly, the number of turns Nᵢ of the inner coils 44 is smaller than the number of turns Nₒ of the outer coils 45, i.e., the inner coils have at least one turn less.

In the present case, good results were achieved with a number of turns Nₒ=26 of the outer coils 45 and a number of turns Nᵢ=20 or Nᵢ=13 of the inner coils 44. The cross section of the individual turns is the same in this case.

In another embodiment it is also possible to make the cross-sectional area of the inner coils 44 smaller than the cross-sectional area of the outer coils 45.

In the embodiment, the device 30 for compensating a magnetic interference field also comprises a device for measuring the magnetic flux density, i.e., for capturing or measuring a magnetic interference field. In the illustrated embodiment, two such devices 24 for measuring the magnetic flux density are provided and schematically indicated, with one of the two devices 24 located in the vicinity of the sample 90 and another one further away therefrom, in particular in the vicinity of the path of the electrically charged particles during operation.

The device 24 for measuring the magnetic flux density comprises at least one sensor which may be in the form of a magnetic field sensor or fluxgate magnetometer or saturation core magnetometer. The device 24 arranged in the vicinity of the sample 90 is designed to be vacuum-compatible.

Furthermore, a power supply for the compensation coils and a device for controlling and/or regulating the current in the compensation coils as a function of the detected or measured magnetic interference field are provided (not shown).

This allows to apply a current individually for each compensation coil or for each conductor, which current may be in a range between 1 and 3 A, for example, so that the desired compensation field can be generated.

Furthermore, at least one device for controlling the compensation coils is provided, preferably on the basis of the measurement of the magnetic flux density, wherein each individual compensation coil of the pair of compensation coils or the pair of compensation coils for magnetic field compensation can be controlled by the control device.

It will be appreciated that before commissioning or before operation, measurements can be carried out to determine the existing interference field, i.e., to determine the presence of magnetic radiation, for example geomagnetic fields, in order to calibrate the device 30.

The apparatus makes it possible to provide a compensated magnetic flux density which is less than 1 μT, preferably less than 0.8 μT, and most preferably less than 0.6 μT, less than 0.4 μT, and in particular 0.2 μT or less within the compensation volume in at least one spatial direction during operation. In the illustrated embodiment, this spatial direction is the spatial direction Z.

Here, the compensation volume within which magnetic fields can be suppressed by 90% or more can have an extent in the spatial direction Z of at least 0.5 m, preferably at least 1 m, and most preferably at least 1.5 m or even more. The extent in a plane perpendicular thereto is at least 0.2 m×0.2 m, preferably at least 0.3 m×0.3 m, more preferably at least 0.4 m×0.4 m, at least 0.5 m×0.5 m or more. During operation, the homogeneous compensation volume with a magnetic flux density reduced by 90% or more will be provided within this cuboid-shaped spatial volume in this embodiment.

The present disclosure thus also provides a method for imaging and/or analyzing and/or processing a sample with high resolution by means of electrically charged particles, in particular using an electron beam, which uses an apparatus 100 for imaging and/or analyzing a sample with high resolution by means of electrically charged particles according to the present disclosure.

The method contemplates that electrically charged particles can be provided by a device for guiding the electrically charged particles 1 along a central direction M_{Z} towards the chamber 19 and to direct them onto a sample 90 arranged in the chamber 19, and that a sample 90 arranged in the chamber 19 can be subjected to the electrically charged particles during operation. The chamber 19 is arranged within the compensation volume in this case.

The method according to the present disclosure can be carried out using the apparatus 100 according to the present disclosure as described above.

The apparatus 100 according to the present disclosure is in particular configured for performing the method according to the present disclosure.

In this way, it is possible to provide a resolution of down to 100 pm, preferably down to 60 pm, and more preferably down to 50 pm, or even down to 40 pm using the apparatus 100 according to the present disclosure, in particular in conjunction with a scanning or transmission electron microscope as shown in FIG. 6a or 6b.

The samples may have structural elevations in the central direction M_{Z} in a range from 1 nm up to several micrometers, preferably up to at least 3 μm or more.

The apparatus 100 according to the present disclosure and the method according to the present disclosure for magnetic field compensation can be used in particular on or in conjunction with scanning and/or transmission electron microscopes (REM or TEM).

The apparatus can also be integrated into existing control concepts, or the prior art control concepts can be enhanced.

This provides a particularly high level of flexibility. This allows for a flexible configuration. For this purpose, the apparatus 100 can be provided in modular form or as a module or in the form of individual modules and can be easily assembled on site.

This also makes it possible to provide magnetic field compensation for rather large scanning and/or transmission electron microscopes with a large overall height or high superstructures, which can be 1 m or higher, or 2 m or higher, or even 3 m, or even higher. This means that significantly smaller rooms can be used than was previously the case.

Finally, the subject matter of this application is presently disclosed in conjunction with several explicit illustrative embodiments and modifications to those embodiments, using various terms. All terms used herein are intended to be merely descriptive, rather than necessarily limiting, and are to be interpreted and construed in accordance with their ordinary and customary meaning in the art, unless used in a context that requires a different interpretation. And for the sake of expedience, each explicit illustrative embodiment and modification is hereby incorporated by reference into one or more of the other explicit illustrative embodiments and modifications. As such, many other embodiments, modifications, and equivalents thereto, either exist now or are yet to be discovered and, thus, it is neither intended nor possible to presently describe all such subject matter, which will readily be suggested to persons of ordinary skill in the art in view of the present disclosure. Rather, the present disclosure is intended to embrace all such embodiments and modifications of the subject matter of this application, and equivalents thereto, as fall within the broad scope of the accompanying claims.

1. An apparatus for imaging and/or analyzing a sample with high resolution by means of electrically charged particles, using an electron beam, comprising:
a device for providing electrically charged particles;
a chamber comprising means for receiving and holding the sample;
a device for guiding the electrically charged particles along a central axis M_{Z} towards the chamber; and
a detector;
wherein the sample arranged in the chamber can be subjected to the electrically charged particles during operation;
and the device for compensating for a magnetic interference field and for establishing a elongated compensation volume that has an extent along the central axis M_{Z};
wherein the chamber is arranged within the elongated compensation volume, at least partially;
comprising at least two compensation coils, each of which is provided by at least one turn of a conductor, and wherein the at least two compensation coils are arranged next to each other along the central axis M_{Z} or associated therewith;
wherein the magnetic interference field can be reduced within the elongated compensation volume during operation.

2. The apparatus according to claim 1, wherein at least one further compensation coil is associated with an X coordinate and a further compensation coil is associated with a Y coordinate, with the X and Y coordinates being orthogonal to the central axis M_{Z}.

3. The apparatus according to claim 1, wherein the elongated compensation volume has an approximately cuboid shape, wherein, preferably, an extent thereof along a direction of the central axis M_{Z} is at least 1.5 times, more at least twice the extent in a direction perpendicular thereto.

4. The apparatus according to claim 1, wherein the compensation coils associated with spatial direction Z are each provided in the form of a pair of compensation coils.

5. The apparatus according to claim 1, wherein the at least two compensation coils are provided in the form of a pair of compensation coils.

6. The apparatus according to claim 1, wherein a distance between an emitter and a sample holder and/or a distance between the sample holder and the detector is 0.5 m or more; and/or wherein a distance between the emitter and the detector is 1 m or more.

7. The apparatus according to claim 6, wherein at a location of the emitter and/or of the sample holder and/or of the detector, a magnetic flux density is 0.2 μT or less.

8. The apparatus according to claim 7, wherein a difference in a magnitude of the magnetic flux density at least at two sensitive locations comprising the emitter, the sample holder, and/or the detector is 0.05 μT or less.

9. The apparatus according to claim 1, wherein the elongated compensation volume has a cuboid-shaped extension, wherein a longest extent, in the direction of a central axis M_{Z}, is at least 0.5 m, and wherein the extent in a plane orthogonal thereto is at least 0.2 m×0.2 m.

10. The apparatus according to claim 1, wherein at least one inner coil of the at least two compensation coils associated with the central axis M_{Z} have a smaller number of turns than at least one outer coil of the at least two compensation coils associated with the central axis M_{Z}.

11. The apparatus according to claim 1, wherein a cross section of the conductor loops belonging to the at least one inner coil through which current can flow during operation is smaller than a cross section of the conductor loops belonging to the at least one outer coil through which current can flow by at least 10% and at most 70%.

12. The apparatus of claim 1, wherein the at least two compensation coils associated with the central axis M_{Z} are arranged on an outer surface and/or an inner surface of a chamber wall.

13. The apparatus according to claim 1, wherein at least one receiving area is provided, which extends in a chamber wall, comprising a recess the.

14. The apparatus according to claim 1, further comprising at least one device for measuring magnetic flux density.

15. The apparatus according to claim 15, wherein the at least one device for measuring a magnetic flux density is arranged inside or in a vicinity of the chamber.

16. The apparatus according to claim 15, wherein the at least one device for measuring the magnetic flux density comprises at least one sensor, or a magnetic field sensor or fluxgate magnetometer or saturation core magnetometer, wherein the at least one device for measuring measures in three spatial directions.

17. The apparatus according to claim 16, further comprises a device for controlling the compensation coils, or on a basis of a measurement of the magnetic flux density, in such a way that each individual compensation coil of the at least two compensation coils or the at least two compensation coils for magnetic field compensation are controllable by the device for controlling.

18. The apparatus according to claim 1, wherein a reduced magnetic flux density can be provided in at least a spatial direction Z along the central axis M_{Z} during operation, wherein the reduced magnetic flux density is over a length of at least 500 mm.

19. A vibration isolation system comprising at least one arrangement mounted with vibration isolation, the system comprises at least one apparatus for imaging and/or analyzing a sample with high resolution by means of electrically charged particles according to claim 1.

20. A method for imaging and/or analyzing a sample with high resolution by means of electrically charged particles, which uses the apparatus for imaging and/or analyzing a sample with high resolution by means of electrically charged particles according to claim 1.

21. The method for high-precision measurement of claim 20, wherein resolution is up to 100 pm.

22. The method for high-precision measurement of claim 20, where the sample can have structural elevations in spatial direction Z in a range from 1 nm up to several micrometers.
